(19) United States
(12) Patent Application Publication
(10) Pub. No.: US 2026/0033156 A1
(43) Pub. Date: Jan. 29, 2026

(54) MOTHER SUBSTRATE FOR DISPLAY DEVICE

(71) Applicant: Japan Display Inc., Tokyo (JP)

(72) Inventors: Sho YANAGISAWA, Tokyo (JP); Nobuo IMAI, Tokyo (JP); Hiroshi OGAWA, Tokyo (JP)

(73) Assignee: Japan Display Inc., Tokyo (JP)

(21) Appl. No.: 19/280,192

(22) Filed: Jul. 25, 2025

(30) Foreign Application Priority Data
Jul. 26, 2024 (JP) 2024-121090

(51) Int. Cl. H10K 59/122; H10K 59/12

(52) U.S. Cl. CPC H10K 59/122; H10K 59/1201

(57) ABSTRACT

According to one embodiment, a display device includes a plurality of panel portions each having a display area, a margin area around the plurality of panel portions, a plurality of display elements provided in the display area, a first partition provided in each of the plurality of panel portions, surrounding the plurality of display elements, and having an overhang shape, and a second partition provided in the margin area and having an overhang shape. Further, a first coverage ratio indicative of a ratio of a total area of the first partition and the second partition relative to a total area of the plurality of panel portions and the margin area is 30% or more.

### CROSS-REFERENCE TO RELATED APPLICATIONS

This application is based upon and claims the benefit of priority from Japanese Patent Application No. 2024-121090, filed Jul. 26, 2024, the entire contents of which are incorporated herein by reference.

### FIELD

Embodiments described herein relate generally to a mother substrate for a display device.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device according to an embodiment.

FIG. 2 is a schematic plan view showing an example of the layout of subpixels.

FIG. 3 is a schematic cross-sectional view of a display device DSP along the line III-III in FIG. 2.

FIG. 4 is a schematic plan view of a mother substrate according to an embodiment.

FIG. 5 is a plan view showing part of the mother substrate in an enlarged manner.

FIG. 6 is a schematic cross-sectional view of the mother substrate along the VI-VI line of FIG. 4.

FIG. 7 is a schematic cross-sectional view of the mother substrate along the VII-VII line of FIG. 4.

FIG. 8A is a schematic cross-sectional view showing the manufacturing process of the display device.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 8G is a schematic cross-sectional view showing a process following FIG. 8F.

FIG. 8H is a schematic cross-sectional view showing a process following FIG. 8G.

FIG. 8I is a schematic cross-sectional view showing a process following FIG. 8H.

FIG. 8J is a schematic cross-sectional view showing a process following FIG. 8I.

FIG. 9 is a schematic cross-sectional view of a mother substrate of a comparative example.

### DETAILED DESCRIPTION

In general, according to one embodiment, a display device includes a plurality of panel portions each having a display area, a margin area around the plurality of panel portions, a plurality of display elements provided in the display area, a first partition provided in each of the plurality of panel portions, surrounding the plurality of display elements, and having an overhang shape, and a second partition provided in the margin area and having an overhang shape. Further, a first coverage ratio indicative of a ratio of a total area of the first partition and the second partition relative to a total area of the plurality of panel portions and the margin area is 30% or more.

This configuration can improve the yield of the display device.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

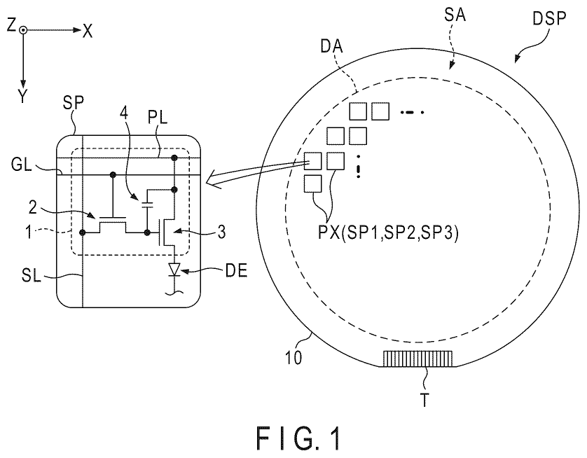

FIG. 1 is a view showing a configuration example of a display device DSP according to an embodiment. The display device DSP comprises an insulating substrate 10. The substrate 10 has a display area DA for displaying an image and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP which display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL supplying the pixel circuit 1 of each subpixel SP with scanning signals, a plurality of signal lines SL supplying the pixel circuit 1 of each subpixel SP with video signals, and a plurality of power lines PL. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of the source electrode and the drain electrode is connected to the power line PL and the capacitor 4. The other is connected to the display element DE.

The configuration of the pixel circuit 1 is not limited to the illustrated example. For example, the pixel circuit 1 may comprise more thin-film transistors and capacitors.

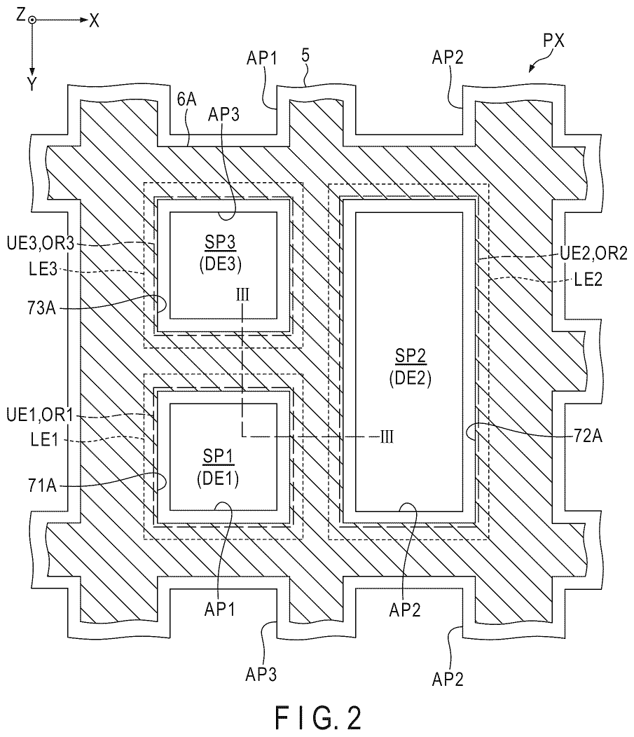

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the subpixels SP1, SP2, and SP3, respectively.

In the example of FIG. 2, the pixel apertures AP1 and AP3 are rectangles having the same planar size. In contrast, the pixel aperture AP2 is a rectangle that is elongated in the Y-direction more than the pixel apertures AP1 and AP3 are. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Portions that overlap the pixel aperture AP1 of the lower electrode LE1, the upper electrode UE1, and the organic layer OR1 constitute a display element DE1 of the subpixel SP1. Portions that overlap the pixel aperture AP2 of the lower electrode LE2, the upper electrode UE2, and the organic layer OR2 constitute a display element DE2 of the subpixel SP2. Portions that overlap the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6A (the first partition) is provided above the rib layer 5. The partition 6A functions as lines that apply common voltage to the upper electrodes UE1, UE2, and UE3. The partition 6A entirely overlaps the rib layer 5 and has the same planar shape as that of the rib layer 5.

The partition 6A surrounds each of the pixel apertures AP1, AP2, and AP3. More specifically, the partition 6A has partition apertures 71A, 72A, and 73A (the first partition apertures) respectively surrounding the pixel apertures AP1, AP2, and AP3.

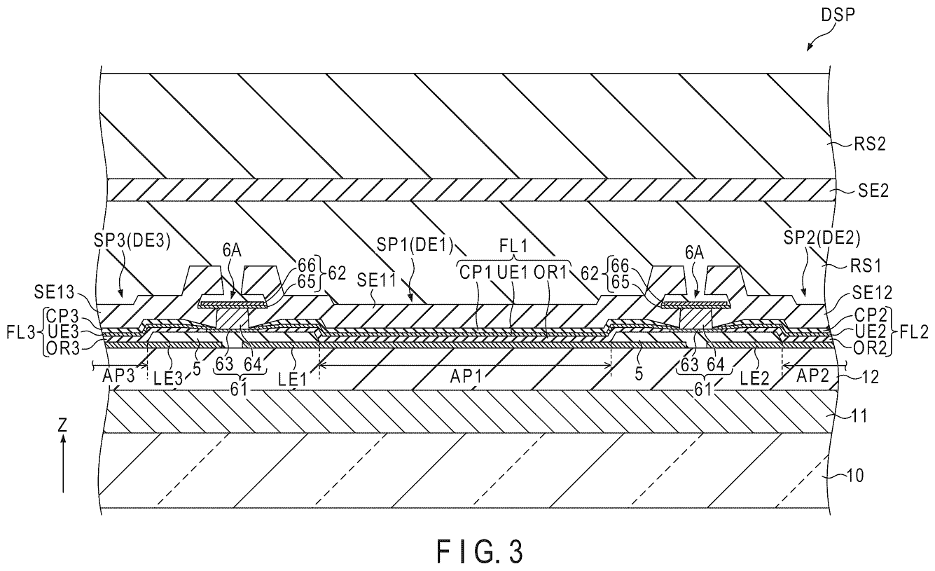

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2, and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has the width greater than that of the lower portion 61. That is, the partition 6A has an overhang shape in which the both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the stem layer 64 is thicker than the bottom layer 63. In the example of FIG. 3, the both end portions of the bottom layer 63 protrude relative to the side surfaces of the stem layer 64.

In the example of FIG. 3, the upper portion 62 comprises a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6A.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 are provided in the subpixels SP1, SP2, and SP3, respectively. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 3, the sealing layer SE11 located on the partition 6A between the subpixels SP1 and SP2 is spaced apart from the sealing layer SE12 located on this partition 6A. The sealing layer SE11 located on the partition 6A between the subpixels SP1 and SP3 is spaced apart from the sealing layer SE13 located on this partition 6A. Two of the sealing layers SE11, SE12, and SE13 may contact each other above the partition 6A.

For example, a gap is formed between each of the sealing layers SE11, SE12, and SE13 and the upper portion 62 of the partition 6A. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The electrodes that constitute the touch panel may be provided on the sealing layer SE2. Further, color filters respectively corresponding to the colors of the subpixels SP1, SP2, and SP3 may be respectively provided above the display elements DE1, DE2, and DE3.

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating material) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), and an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and, OR3 each may have other structures such as a tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

Each of the bottom layer 63 and stem layer 64 of the partition 6A is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

The first top layer 65 of the partition 6A is formed of, for example, a metal material. The second top layer 66 of the partition 6A is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, ITO or IZO can be used. The upper portion 62 may comprise three or more layers or may consist of a single layer. The upper portion 62 may further include a layer formed of an insulating material.

Common voltage is applied to the partition 6A. This common voltage is applied to each of the upper electrodes UE1, UE2, and UE3, which contact the lower portions 61. The lower electrodes LE1, LE2, and LE3 each are supplied with pixel voltages according to the video signals of the signal lines SL through the pixel circuits 1 of the respective subpixels SP1, SP2, and SP3.

The organic layers OR1, OR2, and OR3 emit light according to applied voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light in the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

In the manufacturing of the display device DSP, a large mother substrate is fabricated, the mother substrate comprising a plurality of areas (panel portions) each corresponding to the display device DSP. The following describes a configuration applicable to this mother substrate.

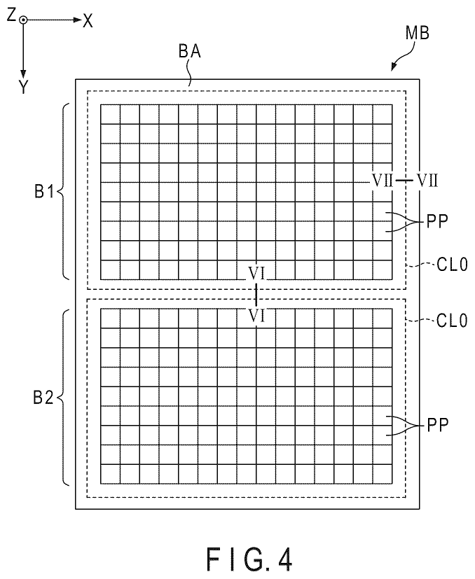

FIG. 4 is a schematic plan view of a mother substrate MB (a mother substrate for a display device) according to the present embodiment. The mother substrate MB has a plurality of panel portions PP provided in a matrix and a margin area BA around these panel portions PP.

In the example of FIG. 4, blocks B1 and B2 (the first and second blocks) are formed on the mother substrate MB. Each of these blocks B1 and B2 includes a plurality of panel portions PP provided to closely contact each other without interposing the margin area BA therebetween. The margin area BA is formed between the blocks B1 and B2 as well. That is, the margin area BA includes portions located in the surrounding of each of the blocks B1 and B2 and a portion located between the blocks B1 and B2.

A cut line CL0 for cutting out the blocks B1 and B2 is set in the mother substrate MB. For example, in the cut line CL0, at least one of the layers such as the rib layer 5, a plurality of insulating layers included in the circuit layer 11, the organic insulating layer 12 are removed.

The configuration of the mother substrate MB is not limited to the example of FIG. 4. For example, the mother substrate MB may have more blocks and cut lines CL0.

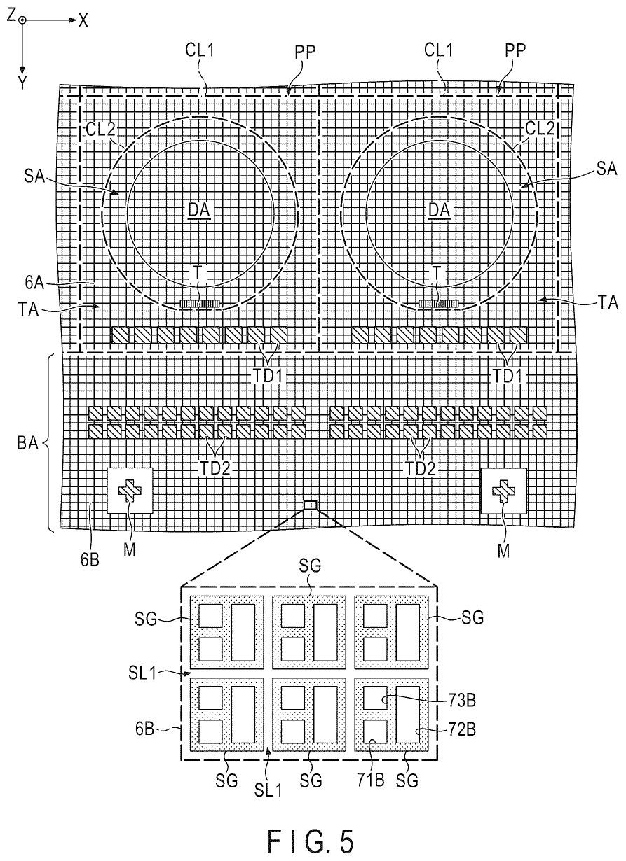

FIG. 5 is a plan view showing part of the mother substrate MB in an enlarged manner. This figure shows two panel portions PP and the margin area BA around them.

The outer shape of the panel portion PP corresponds to a cut line CL1 for cutting out each panel portion PP from the mother substrate MB. Each panel portion PP has the display area DA and the surrounding area SA. The surrounding area SA in the panel portion PP corresponds to the area between the display area DA and the cut line CL1.

The surrounding area SA further has a cut line CL2, which is the outer shape of the substrate 10 of the display device DSP. The cut line CL2 surrounds the display area DA. The surrounding area SA includes an inspection area TA between the cut lines CL1 and CL2.

In the example of FIG. 5, a plurality of inspection pads TD1 are provided in the inspection area TA. Further, a plurality of inspection pads TD2 and a plurality of alignment marks M are provided in the margin area BA. The inspection pads TD1 and TD2 are used to inspect the operations of the display device DSP. The alignment mark M is used to decide a position of the mother substrate MB in manufacturing processes.

The partition 6A is provided not only in the display area DA but also in the surrounding area SA and the inspection area TA. Further, a partition 6B (the second partition) is provided in the margin area BA. The partition 6B has an overhang shape in the same manner as the partition 6A.

More specifically, in the same manner as the partition 6A shown in FIG. 3, the partition 6B comprises the lower portion 61 including the bottom layer 63 and the stem layer 64 and the upper portion 62 including the first top layer 65 and the second top layer 66. The materials of the bottom layer 63, the stem layer 64, the first top layer 65, and the second top layer 66 of the partition 6B are the same as those of the bottom layer 63, the stem layer 64, the first top layer 65, and the second top layer 66 of the partition 6A.

FIG. 5 indicates the area in which the partitions 6A and 6B are provided by a grating pattern. This grating pattern itself does not show the shape of the partitions 6A and 6B. For example, the partition 6A of the display area DA has the plan shape shown in FIG. 2. At least part of the partition 6A of the surrounding area SA may have the same shape as the partition 6A of the display area DA. Alternatively, the entire partition 6A of the surrounding area SA may have a shape different from this shape.

The lower part of FIG. 5 shows an example of the plan shape applicable to the partition 6B. In this example, a slit SL1 divides the partition 6B into a plurality of segments SG. For example, these segments SG have a rectangular shape and are arranged at the same pitch as that of the pixels PX in the X-direction and the Y-direction.

The segment SG has partition apertures 71B, 72B, and 73B (the second partition apertures). The shape and positional relationship of these partition apertures 71B, 72B, and 73B are the same as those of the partition apertures 71A, 72A, and 73A shown in FIG. 2.

The shape of the partition 6B is not limited to the example shown in FIG. 5. For example, the partition 6B may have a segment without a partition aperture, or a linear segment in addition to the illustrated segments SG. Further, the partition 6B may not be divided by the plurality of segments SG. The shape of the partition aperture provided in the partition 6B may differ from those of the partition apertures 71A, 72A, and 73A.

The partition 6A may be provided in the most of the panel portion PP. Similarly, the partition 6B is provided in the most of the margin area BA. However, the partitions 6A and 6B may not be provided at the positions that overlap the terminal portion T, the inspection pads TD1 and TD2, the cut lines CL0, CL1, and CL2, and the alignment mark M.

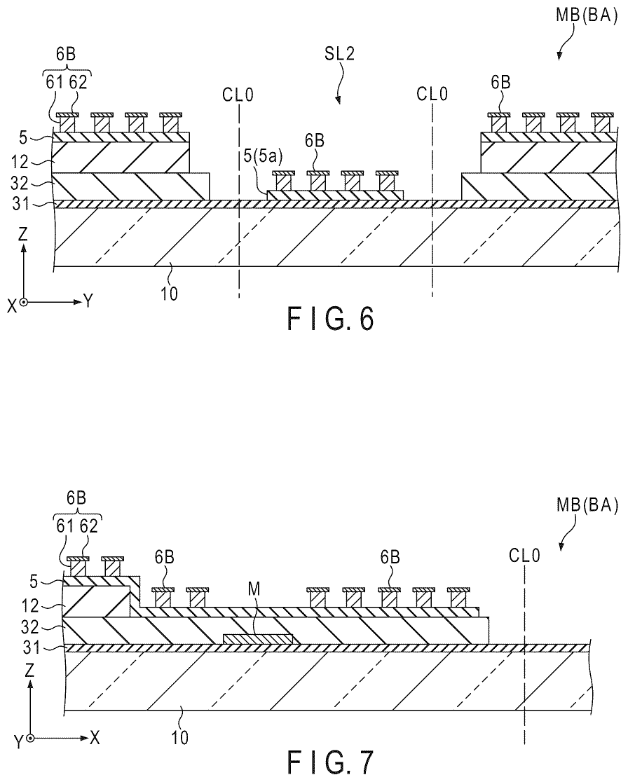

FIG. 6 is a schematic cross-sectional view of the mother substrate MB along the VI-VI line of FIG. 4. In this cross section, an inorganic insulating layer 31 is provided on the substrate 10. Further, an organic insulating layer 32 is provided on the inorganic insulating layer 31. These inorganic insulating layer 31 and organic insulating layer 32 are included in the circuit layer 11 shown in FIG. 3. For example, the inorganic insulating layer 31 is formed of an inorganic insulating material such as a silicon nitride, a silicon oxide, or a silicon oxynitride. For example, the organic insulating layer 32 is formed of an organic insulating material such as a polyimide.

The organic insulating layer 32 is covered with the organic insulating layer 12. The organic insulating layer 12 is covered with the rib layer 5. The partition 6B is provided on the rib layer 5.

The organic insulating layers 12 and 32 are not provided in the cut line CL0 and its vicinity. That is, each of the organic insulating layers 12 and 32 has a slit SL2 along the cut line CL0. The inorganic insulating layer 31 covers the substrate 10 in the slit SL2 as well.

The rib layer 5 and the partition 6B are not provided in the cut line CL0, either. However, in the example of FIG. 6, a rib layer 5 (hereinafter referred to as a rib layer 5a) is provided in the area between two cut lines CL0. The rib layer 5a extends along two cut lines CL0 in plan view. Further, the rib layer 5a contacts the inorganic insulating layer 31. The partition 6B is provided not only on the rib layer 5 outside the slit SL2 but also on the rib layer 5a in the slit SL2.

FIG. 7 is a schematic cross-sectional view of the mother substrate MB along the VII-VII line of FIG. 4. In this cross section, the organic insulating layers 12 and 32 are not provided in the cut line CL0 and its vicinity.

The cross section of FIG. 7 includes the alignment mark M. For example, the alignment mark M is formed by a metal layer included in the circuit layer 11 shown in FIG. 3. In the example of FIG. 7, the alignment mark M is provided on the inorganic insulating layer 31 and is covered with the organic insulating layer 32 (the first organic insulating layer).

In the example of FIG. 7, the organic insulating layer 12 (the second organic insulating layer) is not provided above the alignment mark M. This configuration allows the rib layer 5 to contact the organic insulating layer 32. As another example, the organic insulating layer 12 may be provided above the alignment mark M.

The partition 6B is provided also in the area where the organic insulating layer 32 contacts the rib layer 5. However, the partition 6B is not provided above the alignment mark M.

FIG. 6 and FIG. 7 omit the illustration of the components provided above the rib layer 5 and the partition 6B. The rib layer 5 and the partition 6B are covered with the sealing layer formed of an inorganic insulating material. For example, this sealing layer may be formed of any of the sealing layers SE11, SE12, and SE13. Further, this sealing layer may be covered with the sealing layer SE2. Any of the stacked films FL1, FL2, and FL3 may be provided at least partially below the sealing layer.

The configurations shown in FIG. 6 and FIG. 7 are applicable to the vicinity of each of the cut lines CL1 and CL2 as well. That is, the organic insulating layers 12 and 32 may have slits along the cut lines CL1 and CL2, respectively. The partitions 6A and 6B may be provided in these slits.

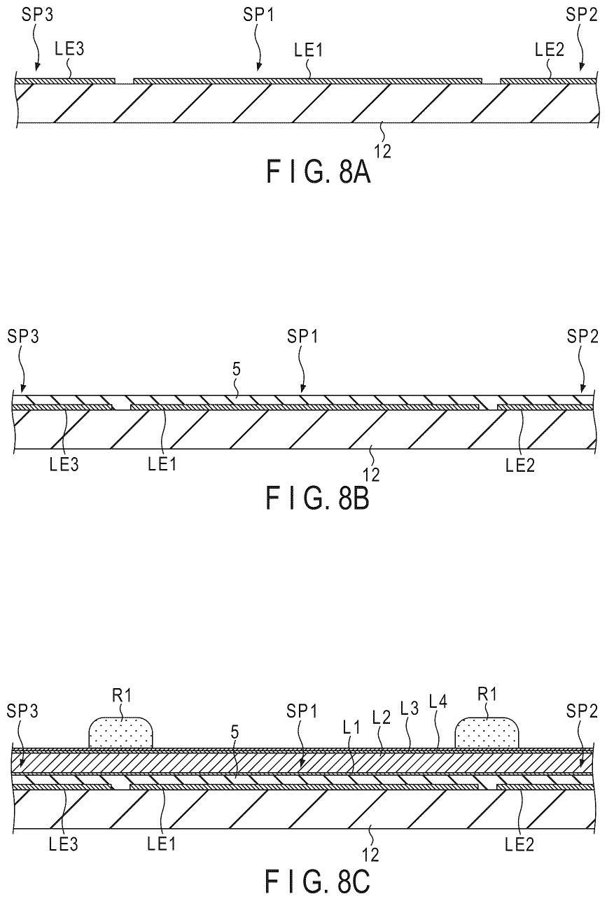

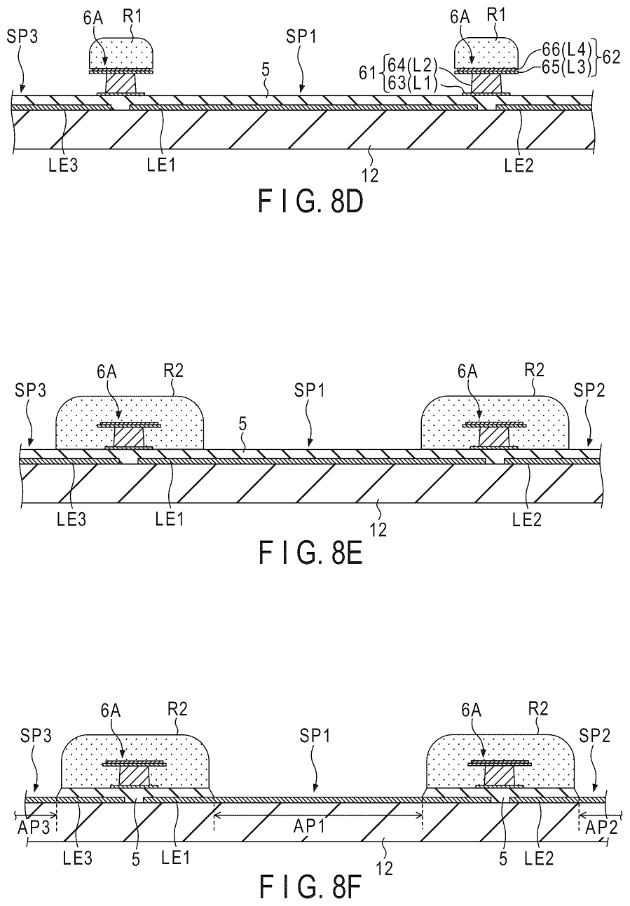

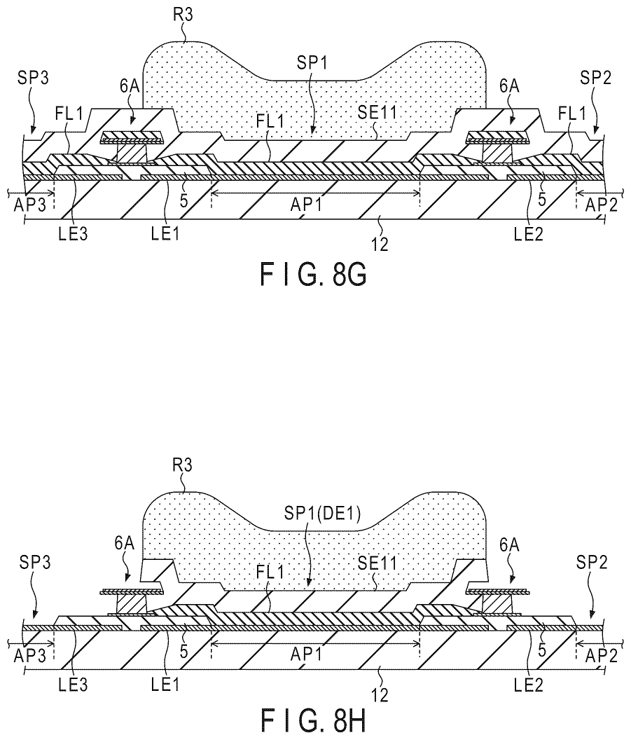

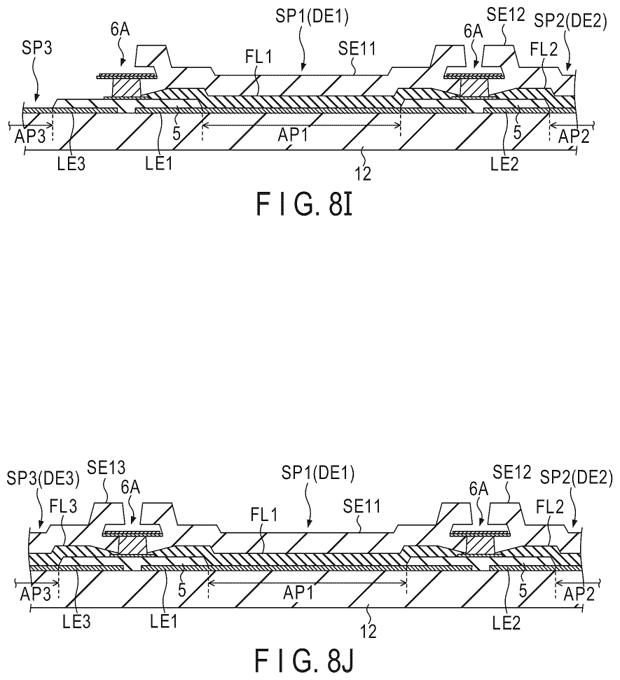

The following describes an example of the manufacturing method of the display device DSP. FIG. 8A to FIG. 8J are schematic cross-sectional views showing the manufacturing process of the display device DSP. FIG. 8A to FIG. 8J mainly focus on the display area DA and omit the components below the organic insulating layer 12.

In the formation of the panel portions PP, first, the circuit layer 11 and the organic insulating layer 12 are formed above the substrate 10 of the mother substrate MB. Next, as shown in FIG. 8A, the lower electrodes LE1, LE2, and LE3 may be formed on the organic insulating layer 12.

Next, the rib layer 5 covering the lower electrodes LE1, LE2, and LE3 are provided on the entire mother substrate MB as shown in FIG. 8B. At this time, the pixel apertures AP1, AP2, and AP3 are not provided in the rib layer 5. The rib layer 5 may be formed by chemical vapor deposition (CVD).

After the formation of the rib layer 5, a process for forming the partitions 6A and 6B is performed. In this process, as shown in FIG. 8C, a first layer L1 processed to be the bottom layer 63, a second layer L2 processed to be the stem layer 64, a third layer L3 processed to be the first top layer 65, and a fourth layer L4 processed to be the second top layer 66 are subsequently formed in the entire mother substrate MB. Further, a resist R1 is provided on the fourth layer L4. The resist R1 has been patterned into the shapes of the partitions 6A and 6B. The first layer L1, the second layer L2, the third layer L3, and the fourth layer L4 are formed by, for example, sputtering.

Subsequently, the first layer L1, the second layer L2, the third layer L3, and the fourth layer L4 are patterned using the resist R1 as a mask. For example, the first layer L1 is formed of a titanium nitride, the second layer L2 is formed of aluminum, and the third layer L3 is formed of titanium. The fourth layer L4 is formed of ITO. In this case, the above patterning may include wet etching to remove the portion of the fourth layer L4 exposed from the resist R1, dry etching to remove the portion of the third layer L3 exposed from the resist R1, wet etching to remove the portion of the second layer L2 exposed from the resist R1 and to reduce the width of the second layer L2 remaining below the resist R1, and dry etching to remove the portion of the first layer L1 exposed from the resist R1.

The patterning including these etching processes forms the partition 6A in the display area DA and the surrounding area SA as shown in FIG. 8D. Further, the partition 6B is formed in the margin area BA. After the formation of the partitions 6A and 6B, the resist R1 is removed (stripped).

Next, the process for providing the pixel apertures AP1, AP2, and AP3 is performed. In the process, a resist R2 covering the partition 6A is formed as shown in FIG. 8E. Further, dry etching for the rib layer 5 is performed using the resist R2 as a mask. This dry etching forms the pixel apertures AP1, AP2, and AP3 that respectively make the lower electrodes LE1, LE2, and LE3 exposed on the rib layer 5 as shown in FIG. 8F. After the dry etching described above, the resist R2 is removed (stripped). The pixel apertures AP1, AP2, and AP3 may be formed prior to the formation of the partitions 6A and 6B.

Next, the process for forming the display element DE1 is performed. In the formation of the display element DE1, the stacked film FL1 and the sealing layer SE11 are formed first as shown in FIG. 8G. As shown in FIG. 3, the stacked film FL1 includes, the organic layer OR1, which contacts the lower electrode LE1 through the pixel aperture AP1, the upper electrode UE1, which covers the organic layer OR1, and the cap layer CP1, which covers the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed in the entire mother substrate MB including the surrounding area SA and the margin area BA as well as the display area DA of each panel portion PP. The stacked film FL1 is divided into a plurality of portions by the partitions 6A and 6B having an overhang shape. The sealing layer SE11 continuously covers the portions into which the stacked film FL1 is divided, and the partitions 6A and 6B.

Subsequently, the stacked film FL1 and the sealing layer SE11 are patterned. In this patterning, as shown in FIG. 8G, a resist R3 is provided on the sealing layer SE11. The resist R3 covers the subpixel SP1 and part of the partition 6A around the subpixel SP1.

Thereafter, the etching process using the resist R3 as a mask is performed. This process removes the portions that are exposed from the resist R3 of the stacked film FL1 and the sealing layer SE11 as shown in FIG. 8H. This process forms the display element DE1 in the subpixel SP1. For example, this etching process removes the stacked film FL1 and the sealing layer SE11 in the surrounding area SA and the margin area BA. This etching process may include wet etching and dry etching performed in order for the sealing layer SE11, the cap layer CP1, the upper electrode UE1, and the organic layer OR1. After these etching processes, the resist R3 is removed (stripped).

Next, the process for forming the display element DE2 is performed. The display element DE2 can be formed by the same procedure as that of the display element DE1. That is, in the formation of the display element DE2, the stacked film FL2 and the sealing layer SE12 are formed in the entire mother substrate MB. The stacked film FL2 includes the organic layer OR2, which contacts the lower electrode LE2 through the pixel aperture AP2, the upper electrode UE2, which covers the organic layer OR2, and the cap layer CP2, which covers the upper electrode UE2, as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE2 forms the display element DE2 in the subpixel SP2, as shown in FIG. 8I. For example, the etching in this patterning removes the stacked film FL2 and the sealing layer SE12 in the surrounding area SA and the margin area BA.

Next, the process for forming the display element DE3 is performed. The display element DE3 can be formed by the same procedures as those of the display elements DE1 and DE2. That is, in the formation of the display element DE3, the stacked film FL3 and the sealing layer SE13 are formed in the entire mother substrate MB. The stacked film FL3 includes, the organic layer OR3, which contacts the lower electrode LE3 through the pixel aperture AP3, the upper electrode UE3, which covers the organic layer OR3, and the cap layer CP3, which covers the upper electrode UE3, as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3 as shown in FIG. 8J. For example, the stacked film FL3 and the sealing layer SE13 may remain in at least part of the surrounding area SA and margin area BA.

Here, the above description assumes that the display elements DE1, DE2, and DE3 are formed in this order. However, the display elements DE1, DE2, and DE3 may be formed in another order.

After the formations of the display elements DE1, DE2, and DE3, the resin layer RS1, the sealing layer SE2, and the resin layer RS2 are formed in order. The resin layers RS1 and RS2 are formed in each of the panel portions PP, for example, by the ink-jet method. The sealing layer SE2 is formed on the entire mother substrate MB, for example, by CVD.

Next, the mother substrate MB is cut along the cut line CL0. This cuts out blocks including the plurality of panel portions PP (for example, blocks BL1 and BL2 shown in FIG. 4) from the mother substrate MB. Further, each block is cut out along the cut line CL1. This cuts out each panel portion PP. Then, the panel portion PP is cut along the cut line CL2. This completes the display device DSP.

For example, laser cutting with infrared irradiation may be adopted for cutting processes along the cut lines CL0, CL1, and CL2. These cutting processes may be performed by other methods such as scribe cutting.

The stacked films FL1, FL2, and FL3 formed by vapor deposition may have poor adherence to the base. Thus, the stacked films FL1, FL2, and FL3 and the sealing layers SE11, SE12, and SE13 covering these stacked films may be stripped from the base in the manufacturing of the display device DSP.

This stripping tends to occur in cases where the stacked films FL1, FL2, and FL3 are continuously formed in a wide range. In the display area DA, the stacked films FL1, FL2, and FL3 are divided into pieces by the partition 6A. Thus, the stripping is suppressed.

In the present embodiment, the partition 6A is provided in the surrounding area SA as well. Further, the partition 6B is provided in the margin area BA. This configuration divides the stacked films FL1, FL2, and FL3 in the entire mother substrate MB and thus suppresses the stripping.

Further, the configuration of the mother substrate MB according to the present embodiment can achieve effects described below.

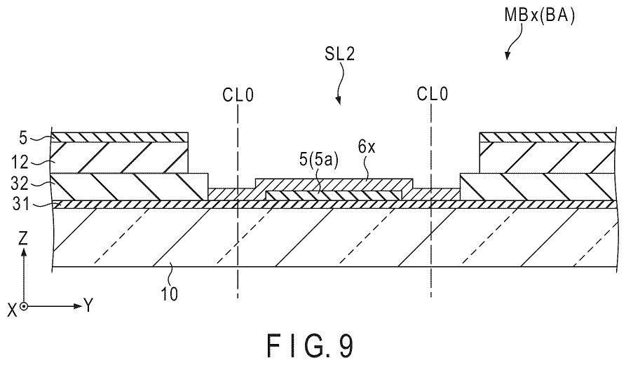

FIG. 9 is a schematic cross-sectional view of a mother substrate MBx of a comparative example for the present embodiment. In the same manner as FIG. 6, FIG. 9 shows the configuration of the vicinity of two cut lines CL0.

In the comparative example, the partition 6B is not provided in the slit SL2 in the organic insulating layers 12 and 32. Further, the partition 6B is not provided on the organic insulating layers 12 and 32 in the vicinity of the slit SL2, either.

In this configuration, residues 6x of the first layer L1, the second layer L2, the third layer L3, and the fourth layer L4 that are to be processed into the partition 6B may be generated in the slit SL2. That is, during patterning of the first layer L1, the second layer L2, the third layer L3, and the fourth layer L4, the amount of each layer to be removed is greater in areas where the partitions 6A and 6B are not formed in a wide range than in areas where the partitions 6A and 6B are formed. Thus, even after etching each layer, some of the layers, in particular, the thicker second layer L2 and the first layer L1 below it may remain.

For example, these residues 6x tend to be generated at positions having steps in the base, such as the slit SL2. The same applies to the vicinity of the slits in the organic insulating layers 12 and 32 along the cut lines CL1 and CL2. Further, the residue 6x may also be generated in the vicinity of steps such as the end portions of the organic insulating layers 12 and 32 shown in FIG. 7.

If the residue 6x overlaps the cut lines CL0, CL1, and CL2, cutting defects may occur. Furthermore, if the residue 6x overlaps the alignment mark M and the inspection pads TD1 and TD2, it may adversely affect the positioning and inspection of the mother substrate MB. Furthermore, the residue 6x has conductivity. Thus, widespread formation of the residue 6x contributes to damage caused by electrostatic discharge (ESD).

The generation of the residue 6x can be suppressed by increasing the intensity of the etching (etching time or etching rate) for the first layer L1, the second layer L2, the third layer L3, and the fourth layer L4, particularly the intensity of the wet etching for the thick second layer L2. However, in this case, the width of the second layer L2 (the stem layer 64) is also greatly reduced at the position where the partitions 6A and 6B should be formed, and thus the protrusion length of the upper portion 62 relative to the side of the stem layer 64 increases. This protrusion length is an important parameter for forming the display elements DE1, DE2, and DE3 in the manner shown in FIG. 8G to FIG. 8J. Thus, changes in the protrusion length entail design review of the display device DSP including other parameters of the partitions 6A and 6B.

In contrast, the present embodiment has the partition 6B provided in the vicinity of the steps of the organic insulating layers 12 and 32 as well, as shown in FIG. 6 and FIG. 7. Further, the partition 6B is provided in the slit SL2 as well. This configuration suppresses the formation of areas where the partition 6B is not formed in the margin area BA, suppressing the generation of the residues 6x.

The effect of suppressing the generation of the residues 6x can be enhanced by setting the first coverage ratio of the partitions 6A and 6B on the mother substrate MB to an appropriate value. Specifically, the first coverage ratio is preferably 30% or more. Here, the first coverage ratio is the ratio of the total area of the partitions 6A and 6B relative to the total area of the plurality of panel portions PP and the margin area BA included in the mother substrate MB (in other words, the area of the entire mother substrate MB). The total area of the partitions 6A and 6B here means the sum of the area of the upper portion 62 of the partition 6A in plan view and the area of the upper portion 62 of the partition 6B in plan view.

Providing many partitions 6B in the margin area BA excessively increases the first coverage ratio, increasing the risk of ESD. Thus, the first coverage ratio is preferably lower than the second coverage ratio in the panel portion PP. The second coverage ratio is the ratio of the area of the partition 6A relative to the area of one panel portion PP. Here, the area of the partition 6A means the area of the upper portion 62 of the partition 6A in plan view.

The inventors prepared the following mother substrates MB1, MB2, and MB3 to verify the coverage ratios of the partitions 6A and 6B and the effects of suppressing the residues 6x. Except for the arrangement of the partitions 6A and 6B, the configurations of the mother substrates MB1, MB2, and MB3 are the same as that of the mother substrate MB according to the present embodiment.
[Mother Substrate MB1] First coverage ratio: 29%, Second coverage ratio: 32%
[Mother substrate MB2] First coverage ratio: 34%, Second coverage ratio: 39%
[Mother substrate MB3] First coverage ratio: 35%, Second coverage ratio: 42%

Among these mother substrates MB1, MB2, and MB3, the mother substrate MB1 with the first coverage ratio of less than 30% exhibited the generation of the residue 6x. On the other hand, the mother substrates MB2 and MB3 with the first coverage ratios of 30% or more exhibited the successful suppression of the residues 6x.

In all of the mother substrates MB1, MB2, and MB3, the first coverage ratio is equal to or less than the second coverage ratio. The generation of ESD was suppressed in all of the mother substrates MB1, MB2, and MB3.

The above indicates setting the first coverage ratio to 30% or more and less than the second coverage ratio can suppress the occurrence of the residue 6x and ESD and improve the yield of the mother substrate MB or display device DSP.

All of mother substrates for display devices that can be implemented by a person of ordinary skill in the art through arbitrary design changes to the mother substrate for a display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A mother substrate for a display device, comprising:
a plurality of panel portions each including a display area;
a margin area around the plurality of panel portions;
a plurality of display elements provided in the display area;
a first partition provided in each of the plurality of panel portions, surrounding the plurality of display elements, and having an overhang shape; and
a second partition provided in the margin area and having an overhang shape, wherein
a first coverage ratio indicative of a ratio of a total area of the first partition and the second partition relative to a total area of the plurality of panel portions and the margin area is 30% or more.

2. The mother substrate of claim 1, wherein
the first coverage ratio is lower than a second coverage ratio indicative of a ratio of the area of the first partition relative to the area of each of the plurality of panel portions.

3. The mother substrate of claim 1, wherein
each of the first partition and the second partition comprises:
a lower portion having conductivity; and
an upper portion having an end portion protruding relative to a side surface of the lower portion,
the lower portions of the first partition and the second partition are formed of a same material, and
the upper portions of the first partition and the second partition are formed of a same material.

4. The mother substrate of claim 3, wherein
the lower portion comprises:
a bottom layer; and
a stem layer thicker than the bottom layer and provided on the bottom layer.

5. The mother substrate of claim 1, further comprising:
an organic insulating layer formed of an organic insulating material on the plurality of panel portions and in the margin area; and
a rib layer formed of an inorganic insulating material on the plurality of panel portions and in the margin area and covering the organic insulating layer, wherein
the rib layer has a plurality of pixel apertures overlapping each of the plurality of display elements in the display area, and
the first partition and the second partition are provided above the rib layer.

6. The mother substrate of claim 5, wherein
the organic insulating layer, the rib layer, the first partition, and the second partition are not provided on a cut line for cutting out the mother substrate.

7. The mother substrate of claim 6, wherein
the organic insulating layer has a slit along the cut line, and
a part of the second partition is provided in the slit.

8. The mother substrate of claim 7, wherein
a part of the rib layer is provided in the slit, and
the part of the second partition is provided above the part of the rib layer.

9. The mother substrate of claim 8, further comprising:
an inorganic insulating layer formed of an inorganic insulating material and located below the organic insulating layer, wherein
the part of the rib layer provided in the slit contacts the inorganic insulating layer.

10. The mother substrate of claim 6, wherein
the margin area includes an alignment mark formed of a metal material and located below the organic insulating layer, and
the second partition is not provided at a position overlapping the alignment mark.

11. The mother substrate of claim 10, further comprising:
an inorganic insulating layer formed of an inorganic insulating material and located below the organic insulating layer, wherein
the alignment mark is provided above the inorganic insulating layer and is covered with the organic insulating layer.

12. The mother substrate of claim 11, wherein
the organic insulating layer includes a first organic insulating layer and a second organic layer covering the first organic insulating layer,
the first organic insulating layer is provided above the alignment mark, and
the second organic insulating layer is not provided above the alignment mark.

13. The mother substrate of claim 12, wherein
the rib layer contacts the first organic insulating layer above the alignment mark.

14. The mother substrate of claim 6, wherein
the cut line includes a first cut line for cutting out each of the plurality of panel portions, and
the first partition is provided in each of the display area and a surrounding area between the display area and the first cut line in each of the plurality of panel portions.

15. The mother substrate of claim 14, wherein
the cut line further includes a second cut line surrounding the display area in each of the plurality of panel portions, and
the first partition is provided in each of an area between the first cut line and the second cut line and an area between the second cut line and the display area, in the surrounding area of each of the plurality of panel portions.

16. The mother substrate of claim 15, further comprising:
an inspection pad provided between the first cut line and the second cut line, wherein
the first partition is not provided at a position overlapping the inspection pad in plan view.

17. The mother substrate of claim 15, further comprising:
a terminal portion provided in an area between the second cut line and the display area, wherein
the first partition is not provided at a position overlapping the terminal portion in plan view.

18. The mother substrate of claim 5, wherein
the first partition has a plurality of first partition apertures each overlapping the plurality of pixel apertures, and
the second partition has a plurality of second partition apertures each having a shape equivalent to that of the first partition aperture.

19. The mother substrate of claim 18, wherein
the second partition includes a plurality of segments divided by a slit, and
each of the plurality of segments has at least one of the second partition apertures.

20. The mother substrate of claim 1, further comprising:
a first block in which some of the plurality of panel portions are arranged without interposing the margin area; and
a second block in which the other plurality of panel portions are arranged without interposing the margin area, wherein
the margin area includes a portion located between the first block and the second block.
